(19) United States
(12) Patent Application Publication
(10) Pub. No.: US 2025/0006782 A1
(43) Pub. Date: Jan. 2, 2025

(54) ELECTRONIC DEVICE

(71) Applicant: STMicroelectronics International N.V., Geneva (CH)

(72) Inventor: Mohamed BOUFNICHEL, Monnaie (FR)

(73) Assignee: STMicroelectronics International N.V., Geneva (CH)

(21) Appl. No.: 18/744,301

(22) Filed: Jun. 14, 2024

(30) Foreign Application Priority Data
Jun. 27, 2023 (FR) 2306700

(51) Int. Cl. H01G 4/10

(52) U.S. Cl. CPC H01L 28/92; H01L 28/88

(57) ABSTRACT

The present description concerns an electronic device comprising at least two three-dimensional capacitors, each capacitor being surrounded with a trench comprising a gas pocket.

### CROSS-REFERENCE TO RELATED APPLICATION(S)

This application claims the priority benefit of French patent application number FR2306700, filed on Jun. 27, 2023, entitled “Dispositif électronique,” which is hereby incorporated by reference to the maximum extent allowable by law.

### BACKGROUND

### Technical Field

The present disclosure generally concerns electronic devices and their manufacturing methods, as well as relates to devices comprising three-dimensional capacitors.

### Description of the Related Art

There exist several types of capacitors. A particularly common type of capacitor corresponds to so-called MOM, or metal-oxide-metal, capacitors. Such capacitors comprise a stack of two conductive layers, preferably made of metal, separated by an insulating layer, preferably made of oxide, for example, of silicon oxide.

MOM capacitors may for example be planar, that is, the stack covers a planar layer. MOM capacitors may also be three-dimensional, that is, covering a non-planar layer, for example comprising cavities. Thus, a three-dimensional capacitor may have a capacitance significantly higher than that of a planar capacitor, for the same chip surface area.

### BRIEF SUMMARY

An embodiment overcomes all or part of the disadvantages of known electronic devices.

An embodiment provides an electronic device comprising at least two three-dimensional capacitors, each capacitor being surrounded with a trench comprising a gas pocket.

Another embodiment provides a method of manufacturing an electronic device comprising the forming of at least two three-dimensional capacitors, each capacitor being surrounded with a trench comprising a gas pocket.

According to an embodiment, the capacitors and the trenches are in a first insulating layer.

According to an embodiment, each capacitor is located in a first region of the first layer, each trench being located in a second region of the first layer separated from the first region by a third region of the first layer.

According to an embodiment, each third region is not covered with conductive material.

According to an embodiment, each capacitor comprises a first stack of two conductive layers separated by an insulating layer, the first stack conformally extending over the first region of the first layer, the first region comprising at least two first cavities, the first stack filling the first cavities.

According to an embodiment, each trench comprises a second stack of layers identical to the first stack, conformally extending in a second cavity, the gas pocket being located in the second cavity, partially delimited by the second stack.

According to an embodiment, the device comprises a second layer closing each second cavity, and partially delimiting the gas pocket located in the second cavity.

According to an embodiment, each first region is covered with a third layer made of the material of the second layer.

According to an embodiment, the second layer extends, in the second cavity, over less than 20% of the height of the second cavity.

According to an embodiment, each gas pocket extends over at least half of the height of the first cavities.

According to an embodiment, the trenches surrounding at least two neighboring capacitors comprise common portions.

According to an embodiment, the trenches surrounding at least two neighboring capacitors are separated from one another by portions of the first layer.

According to an embodiment, the device comprises a filter, the capacitors forming part of the filter.

According to an embodiment, the method comprises: the forming in the first layer of the first and second cavities; the forming of a third stack of two conductive layers separated by an insulating layer in conformal fashion, the first cavities being filled while the second cavities are not filled, the forming of a fourth non-conformal layer closing the second cavities; the etching of the third stack and of the fourth layer in the third regions to form the first and second stacks and the second and third layers.

According to an embodiment, the forming of the fourth layer is performed by a physical vapor deposition method or by a plasma-enhanced chemical vapor deposition method.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1A shows a cross-section view of an embodiment of a device comprising a three-dimensional capacitor;

FIG. 1B shows a top view of the embodiment of FIG. 1A;

FIG. 2A shows a step of a method of manufacturing the device of FIGS. 1A and 1B;

FIG. 2B shows another step of a method of manufacturing the device of FIGS. 1A and 1B;

FIG. 2C shows another step of a method of manufacturing the device of FIGS. 1A and 1B;

FIG. 3 shows two views illustrating two arrangements of the capacitors of FIGS. 1A and 1B.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge,” “back,” “top,” “bottom,” “left,” “right,” etc., or relative positions, such as terms “above,” “under,” “upper,” “lower,” etc., or to terms qualifying directions, such as terms “horizontal,” “vertical,” etc., it is referred, unless specified otherwise, to the orientation of the drawings.

Unless specified otherwise, the expressions “about,” “approximately,” “substantially,” and “in the order of” signify plus or minus 10%, preferably of plus or minus 5%.

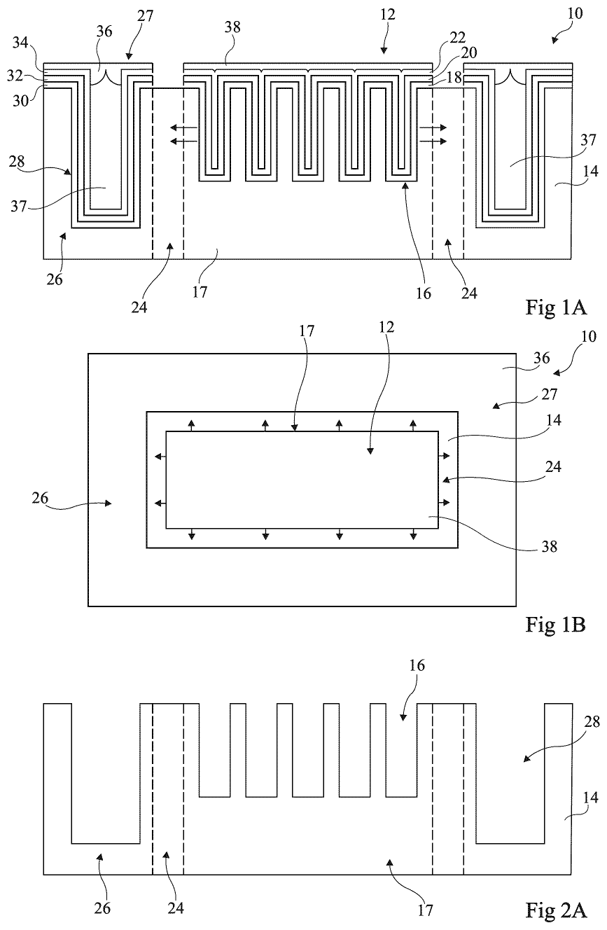

FIG. 1A shows a cross-section view of a device 10 comprising a three-dimensional capacitor 12. FIG. 1B shows a top view of the embodiment of FIG. 1A.

Device 10 comprises an insulating layer 14. Layer 14 is, for example, made of an electrically-insulating material, for example, silicon oxide. Layer 14 for example corresponds to a layer of a metallization level of an interconnection network. Thus, layer 14 for example covers a semiconductor substrate, not shown. Layer 14 for example covers one or a plurality of other insulating layers, for example each comprising metallizations or conductive vias.

Layer 14 comprises a set of cavities 16. Cavities 16 are, for example, identical in size. Each trench 16 extends from an upper surface of layer 14 to an inner level of layer 14. In other words, each trench does not cross layer 14. In other words, the height of cavities 16 is lower than the height of layer 14.

The cavities 16 of the set are all present in a region 17 of layer 14. The cavities 16 of the set are for example arranged in an array in region 17. Each set of cavities 16 for example comprises at least two cavities, between 2 and 3,000 cavities. Each cavity 16 is separated from the nearest cavity 16 of the same set only by a portion of layer 14.

Capacitor 12 is formed inside and on top of cavities 16. Capacitor 12 is, for example, a metal-insulator-metal capacitor. In other words, capacitor 12 comprises a conductive layer 18, an insulating layer 20, and a conductive layer 22. Conductive layers 18 and 22 are for example made of metal. Layer 20 is made of a dielectric material.

Layer 18, corresponding to a lower electrode of capacitor 12, covers the walls and bottom of the cavities 16 of the set. Layer 18 further covers the portions of the upper surface of layer 14 located between cavities 16 and covers portions of the upper surface of layer 14 around cavities 16. In other words, layer 18 entirely covers the upper surface of region 17 of layer 14 and the inside of cavities 16. Layer 18 thus conformally covers region 17 of layer 14.

Layer 20 extends over layer 18, for example over the entire layer 18. Layer 20 conformally extends over layer 18. Layer 20 extends over the portions of layer 18 located in cavities 16 and over the portions of layer 18 located on the upper surface of layer 14.

Layer 22, corresponding to an upper electrode of capacitor 12, extends over layer 20, for example over the entire layer 20. In particular, layer 22 extends in cavities 16, preferably over at least half of the height of cavities 16. The dimensions of cavities 16 and of layers 18, 20, 22 are selected so that cavities 16 are entirely filled with layers 18, 20, 22.

Layers 18, 20, 22 extend in region 17 only. Region 17 is surrounded with a region 24 of layer 14. Layers 18, 20, 22 do not extend over the upper surface of region 24.

Region 24 is preferably only made of the material of layer 14. Region 24 preferably comprises no conductive material. Region 24 is preferably not covered with conductive material.

Layer 14 further comprises a region 26. Region 26 surrounds region 24. Region 26 thus surrounds region 17. Region 26 is separated from region 17 by region 24, preferably at all points.

Device 10 comprises a trench 27. Trench 27 comprises a cavity 28 located in region 26. Cavity 28 forms a ring. Cavity 28 surrounds regions 17 and 24. Thus, cavity 28 surrounds the set of cavities 16.

The dimensions of cavity 28 are preferably greater than the dimensions of one of cavities 16. More specifically, the height of cavity 28 is preferably greater than the height of one of cavities 16. At least one of the dimensions of the opening of cavity 28, that is, the dimensions of cavity 28 in the plane of the upper surface of layer 14, is greater than the dimensions of the opening of one of cavities 16. Preferably, all the dimensions of the opening of cavity 28 are greater than the dimensions of the opening of a cavity 16.

Trench 27 comprises a stack of layers 30, 32, 34 conformally extending in region 26. Layer 30 is made of the same material as layer 18 and has a thickness substantially equal to the thickness of layer 18. Similarly, layer 32 is made of the same material as layer 20 and has a thickness substantially equal to the thickness of layer 20. Similarly, layer 34 is made of the same material as layer 22 and has a thickness substantially equal to the thickness of layer 22.

Layer 30 conformally covers region 26. Thus, layer 30 covers the side walls and bottom of cavity 28. Layer 30 further covers the portions of the upper surface of layer 14 located in region 26.

Layer 32 conformally covers layer 30. Preferably, layer 30 is entirely covered with layer 32. Thus, layer 32 extends in cavity 28 and over the upper surface of region 28.

Layer 34 conformally covers layer 32. Preferably, layer 32 is entirely covered with layer 34. Thus, layer 34 extends in cavity 28 and over the upper surface of region 26.

Layers 30, 32, 34 extend in region 26 only. Layers 30, 32, 34 do not extend over the upper surface of region 24.

Trench 27 also comprises a layer 36. Layer 36 extends over the portions of layer 34 located outside of cavity 28. Thus, layer 36 extends in front of the upper surface of region 26. Layer 36 also extends over the opening of cavity 28. Cavity 28 is thus closed by layer 36. Layer 36 preferably comprises a first portion extending in the plane of the upper surface of layer 14 and second portions extending in an upper portion of the cavity. Preferably, the second portions extend, from the opening of cavity 28, over a height smaller than 20% of the height of cavity 28, preferably smaller than 10% of the height of cavity 28. Layer 36 does not fill the cavity 28. Thus, a cavity, or pocket, 37 filled with gas, for example air, is kept in cavity 28. Pocket 37 is delimited by layer 34 and layer 36. Pocket 37 preferably extends over at least 50% of the height of cavities 16, more preferably over at least 75% of the height of cavities 16.

Device 10 further comprises a layer 38 made of the material of layer 36. Layer 38 preferably entirely covers layer 22.

Layer 36 preferably does not extend over the upper surface of region 24. Similarly, layer 38 preferably does not extend over the upper surface of region 24.

Layers 36 and 38 are for example made of an insulating material or of a conductive material, for example, of a metal.

Device 10 for example comprises connection elements, not shown, enabling to connect the upper 22 and lower 18 electrodes of capacitor 12 to a circuit. The connection elements for example correspond to conductive vias crossing layer 38 to reach layer 22 or crossing layers 20 and 38 in a portion of layer 20 not covered by layer 22, to reach layer 18.

The filling of cavities 16 with layers of materials causes stress on layer 14. More specifically, the filling of cavities 16 with layers of materials causes lateral stress on layer 14, represented by arrows in FIGS. 1A and 1B. The filling of each cavity 16 causes stress, which adds to the stress generated by the other cavities 16. During the forming of a plate only comprising filled cavities 16, the filling of cavities 16 may cause sufficient stress to twist the plate and thus disrupt the manufacturing steps. A twisted plate may not be able to be fed into a machine carrying out a step of the manufacturing method.

Pockets 37 enable to absorb the stress generated by layers 18, 20, 22 in cavities 16. Thus, regions 17 and 24 are submitted to the stress generated by layers 18, 20, 22 located in the cavities 16 of region 17, but are not submitted to the stress generated by other regions 17 located outside of trench 27.

Trenches 27 are preferably electrically insulated. In other words, layers 30, 32, 34 are preferably coupled to no electronic component and to no conductive element. Trenches 27 for example have as only purpose the absorbing of the stress generated by capacitors 12.

The presence of gas in pocket 37 may cause the presence of undesirable elements in the cavity and in contact with layer 34. However, since trenches 27 have no electrical function, the forming of defects on layer 34 does not modify the absorption of the stress generated by capacitor 12.

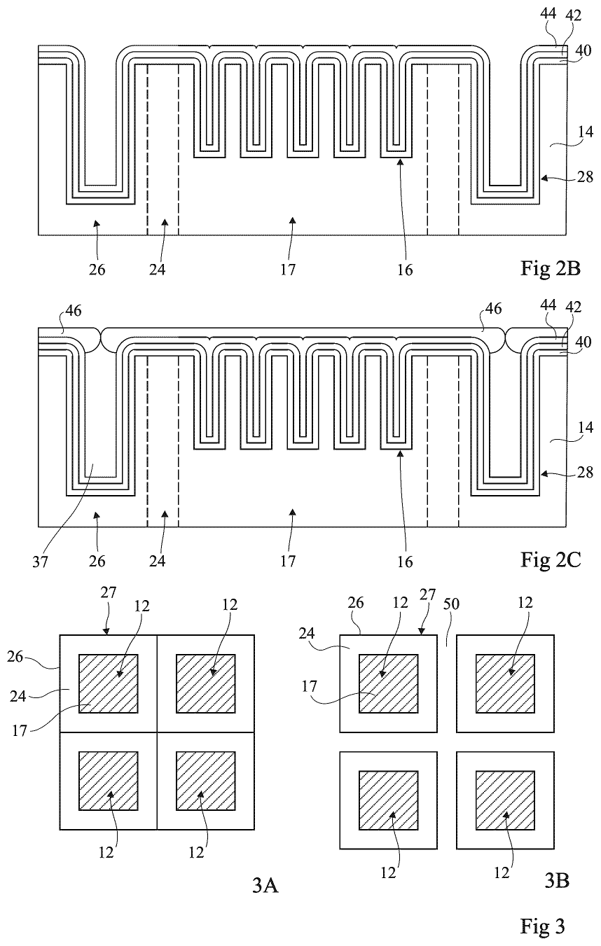

FIGS. 2A to 2C show steps, preferably successive, of a method of manufacturing the device 10 of FIGS. 1A and 1B.

FIG. 2A shows a step of a method of manufacturing the device of FIGS. 1A and 1B.

During this step, layer 14 is formed. Layer 14 is formed, for example, on a substrate or a support, not shown. Layer 14 is for example a planar layer. The upper and lower surfaces of layer 14 are then parallel.

The step of FIG. 2A then comprises the forming of cavities 16 in region 17, and the forming of cavity 28 in region 26. The forming of cavities 16 and 28 is preferably performed simultaneously, by the same etch step.

The forming of cavities 16 and 28 comprises, for example, the forming of a mask, not shown, over the upper surface of layer 14. The mask, not shown, comprises openings facing the locations of cavities 16 and 18, said openings having dimensions substantially equal to the dimensions of the openings of cavities 16 and 18. The forming of the cavities then comprises the etching of layer 14 through the mask openings. The difference between the dimensions of the opening of trenches 16 and the dimensions of the opening of trench 28 results in the height difference of the cavities formed during the etching.

FIG. 2B shows another step of a method of manufacturing the device of FIGS. 1A and 1B.

During this step, a stack of layers 40, 42, 44 is conformally formed over at least regions 17, 24, and 26, preferably over the entire layer 14.

Layer 40 is made of the material of layers 18 and 30. Layer 40 has a thickness substantially equal to the thickness of layers 18 and 30. Layer 42 is made of the material of layers 20 and 32. Layer 42 has a thickness substantially equal to the thickness of layers 20 and 32. Layer 44 is made of the material of layers 22 and 34. Layer 44 has a thickness substantially equal to the thickness of layers 22 and 34.

Layer 40 conformally covers regions 17, 24, 28. Preferably, layer 40 conformally covers the entire layer 14. Thus, layer 40 covers the side walls and the bottom of cavities 16 and 28. Layer 40 further covers the upper surface of regions 17, 24, 26 of layer 14.

Layer 42 conformally covers layer 40. Preferably, layer 42 entirely covers layer 40. In particular, layer 42 covers the portions of layer 40 located in cavities 16 and 28 and on the upper surfaces of regions 17, 24, 26.

Similarly, layer 44 conformally covers layer 42. Preferably, layer 44 entirely covers layer 42. In particular, layer 44 covers the portions of layer 42 located in cavities 16 and 28 and on the upper surfaces of regions 17, 24, 26. Layer 44 has a thickness such that, after the forming of layer 44, cavities 16 are filled with the stack of layers 40, 42, 44. The thicknesses of layers 40, 42, 44 are such that cavity 28 is not filled with layers 40, 42, 44. The dimensions of cavity 28 and of layers 40, 42, 44 are such that, over at least half the height of cavity 28, the portions of layer 44 extending over opposite side walls of cavity 28 are not in contact.

FIG. 2C shows another step of a method of manufacturing the device of FIGS. 1A and 1B.

During this step, a non-conformal layer 46 is formed on the structure resulting from the step of FIG. 2B. Layer 46 is made of the material of layers 36 and 38. Layer 46 is formed in such a way as to close cavity 28, while keeping gas pocket 37 in cavity 28. Layer 46 is formed, for example, by a physical vapor deposition (PVD) method, layer 46 being for example made of metal, or by a plasma-enhanced chemical vapor deposition (PECVD) method, layer 46 being for example made of a dielectric, for example of silicon oxide.

The method further comprises, after the step of FIG. 2C, a step of etching of the portions of layers 40, 42, 44, 46 located on region 24. Layers 18, 20, 22, 30, 32, 34 are thus formed.

The method further comprises the forming of the connection elements, not shown, allowing for the connection of electrodes 18 and 22.

FIG. 3 shows two views 3A and 3B illustrating two arrangements of the capacitors shown in FIGS. 1A and 1B. Each arrangement comprises four capacitors 12. The device may however comprise any number of capacitors 12, for example at least two capacitors. Capacitors 12 are for example used in filters.

In FIG. 3, regions 26, including trenches 27, are shown with single lines, the regions 17 comprising capacitors 12 are shown with hatched rectangles, and the regions 24 separating regions 26 and 17 are shown with the white strips separating the rectangles and the single lines.

According to the embodiment of view 3A, illustrating a first example of arrangement, trenches 27 form a grid, delimiting regions 24. In the embodiment of view 3A, trenches 27 form columns and rows of a grid and delimit an array of locations, each comprising a region 17 and a region 24, preferably a single region 17 and a single region 24. All trenches 27 are thus coupled to one another.

Two neighboring capacitors are separated by a single trench 27. Two neighboring capacitors are thus separated by a portion of region 24, a trench 27, and a portion of another region 24.

According to the embodiment of view 3B, illustrating a second example of arrangement, the device comprises an array of assemblies comprising a region 17, a region 24, and a region 26, the different assemblies being separated from one another by a portion 50 of substrate 14. Trenches 27 are thus independent from one another. In other words, trenches 27 are separated from one another by portions 50.

Two neighboring capacitors are separated by two trenches 27. Two neighboring capacitors are thus separated by a portion of region 24, a trench 27, a portion 50, a trench 27, and a portion of another region 24.

Although, in FIG. 3, capacitors 12 are aligned in rows and in columns, the capacitors may for example be aligned in rows and have offset columns.

Further, the device comprising capacitors 12 may comprise portions where the capacitors are arranged according to the first arrangement and portions where the capacitors are arranged according to the second arrangement.

An advantage of the described embodiments is that it is possible to form plates with a high density of three-dimensional capacitors without causing any deformation.

Another advantage of the described embodiments is that, since trenches 27 are not electrically active, the presence of the gas pocket does not cause any damage and has no impact on the efficiency of the capacitors.

Another advantage of the described embodiments is that the simultaneous forming of trenches 27 and of capacitors 12 enables to avoid the deformation of the plate and enables to avoid adding forming steps.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

An electronic device (10) includes at least two three-dimensional capacitors (12), each capacitor (12) being surrounded with a trench (27) comprising a gas pocket (37).

A method of manufacturing an electronic device (10) includes the forming of at least two three-dimensional capacitors (12), each capacitor (12) being surrounded with a trench (27) comprising a gas pocket (37).

The capacitors (12) and the trenches (27) are in a first insulating layer (14).

Each capacitor (12) is located in a first region (17) of the first layer (14), each trench (27) being located in a second region (26) of the first layer (14) separated from the first region (17) by a third region (24) of the first layer (14).

Each third region (24) is not covered with conductive material.

Each capacitor (12) includes a first stack (18, 20, 22) of two conductive layers separated by an insulating layer, the first stack conformally extends over the first region of the first layer, the first region including at least two first cavities (16), the first stack filling the first cavities (16).

Each trench (27) includes a second stack (30, 32, 34) of layers identical to the first stack (18, 20, 22), conformally extending in a second cavity (28), the gas pocket (37) being located in the second cavity (28), partially delimited by the second stack (30, 32, 34).

The device (10) includes a second layer (36) closing each second cavity (28), and partially delimiting the gas pocket (37) located in the second cavity.

Each first region (17) is covered with a third layer (38) made of the material of the second layer (36).

The second layer (36) extends, in the second cavity (28), over less than 20% of the height of the second cavity.

Each gas pocket (37) extends over at least half of the height of the first cavities (16).

The trenches (27) surrounding at least two neighboring capacitors (12) include common portions.

The trenches (27) surrounding at least two neighboring capacitors (12) are separated from one another by portions (50) of the first layer.

The device includes a filter, the capacitors forming part of the filter.

The method includes the forming in the first layer of first and second cavities; the forming of a third stack of two conductive layers conformally separated by an insulating layer in conformal fashion, the first cavities being filled while the second cavities are not filled, the forming of a fourth non-conformal layer closing the second cavities; the etching of the third stack and of the fourth layer in the third regions to form the first and second stacks and the second and third layers.

The forming of the fourth layer is performed by a physical vapor deposition method or by a plasma-enhanced chemical vapor deposition method.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device comprising:
a first insulating layer;
at least two three-dimensional capacitors in the first insulating layer; and
a plurality of trenches in the first insulating layer surrounding the at least two capacitors, each of the plurality of trenches including a gas pocket.

2. The device according to claim 1, wherein the first insulating layer includes a first plurality of cavities.

3. The device according to claim 2, wherein each capacitor is located in a first region of the first insulating layer and each trench is located in a second region of the first insulating layer separated from the first region along a first direction by a third region of the first insulating layer.

4. The device according to claim 3, wherein each capacitor includes a first stack of two conductive layers separated by a second insulating layer, the first stack extending over the first region of the first insulating layer and filling the first plurality of cavities.

5. The device according to claim 4, wherein each trench of the plurality of trenches includes a second stack of layers having the same layers as the first stack, the second stack extending into a second cavity, the gas pocket being located in the second cavity.

6. The device according to claim 5, wherein each first stack is separated from each second stack along the first direction by a first gap, each first gap overlapping each third region.

7. The device according to claim 5, including a second layer enclosing each of the plurality of trenches and partially delimiting the gas pocket located in the second cavity.

8. The device according to claim 7, wherein each first region is covered with a third layer made of a material of the second layer.

9. The device according to claim 7, wherein the second layer extends, in the second cavity, over less than 20% of the depth of the second cavity along a second direction transverse to the first direction.

10. The device according to claim 6, wherein each gas pocket extends over at least half of the depth of the first cavities along the second direction.

11. The device according to claim 1, wherein the plurality of trenches surrounding the at least two capacitors are shared by the at least two capacitors.

12. The device according to claim 1, wherein the plurality of trenches surrounding the at least two capacitors are separated from one another by a plurality of portions of the first insulating layer.

13. The device according to claim 1, wherein the device comprises a filter including the at least two capacitors.

14. A method comprising:
forming, in a first surface of a first layer, a first and second plurality of cavities;
forming, on the first surface, a first stack of two conductive layers separated by an insulating layer, the first stack being in the first and second pluralities of cavities, the first plurality of cavities being entirely filled;
forming a second layer on the first stack, the second layer enclosing the second plurality of cavities; and
etching the first stack and the second layer, forming a first plurality of gaps between the first and second pluralities of cavities.

15. The method according to claim 14, wherein the forming the second layer is performed by a physical vapor deposition method or by a plasma-enhanced chemical vapor deposition method.

16. The method according to claim 14, wherein each of the second plurality of cavities includes a gas-filled opening.

17. A device comprising:
a first insulating layer with a first surface;
a first plurality of trenches in the first insulating layer extending along a first direction from the first surface;
a second plurality of trenches separated from the first plurality of trenches along a second direction transverse to the first direction, the second plurality of trenches extending along the first direction from the first surface;
an air-filled cavity in each trench of the second plurality of trenches; and
a first stack of layers in the first plurality of trenches.

18. The device according to claim 17, wherein the first stack of layers includes:
a first conductive layer directly on the substrate in the first plurality of trenches;
a second insulating layer on the first conductive layer; and
a second conductive layer on the second insulating layer.

19. The device according to claim 18, further comprising a second stack of layers in each of the second plurality of trenches, the second stack of layers being separated from the first stack of layers along the second direction.

20. The device according to claim 19, further comprising a first cover layer on the second plurality of trenches.
